(19) United States
(12) Patent Application Publication
(10) Pub. No.: US 2024/0194657 A1
(43) Pub. Date: Jun. 13, 2024

(54) INTEGRATED PHOTONIC DEVICE AND ELECTRONIC DEVICE ARCHITECTURES

(71) Applicant: Intel Corporation, Santa Clara, CA (US)

(72) Inventors: Suddhasattwa Nad, Chandler, AZ (US); Brandon Marin, Gilbert, AZ (US); Jeremy Ecton, Gilbert, AZ (US); Gang Duan, Chandler, AZ (US); Srinivas Pietambaram, Chandler, AZ (US)

(73) Assignee: Intel Corporation, Santa Clara, CA (US)

(21) Appl. No.: 18/080,152

(22) Filed: Dec. 13, 2022

(51) Int. Cl. H01L 25/16; G02B 6/42; H01L 21/56; H01L 23/00; H01L 23/433

(52) U.S. Cl. CPC H01L 25/167; G02B 6/4239; G02B 6/4245; G02B 6/4257; G02B 6/4269; H01L 21/565; H01L 23/4334; H01L 24/08; H01L 24/80; G02B 6/426; H01L 24/16; H01L 2224/08121; H01L 2224/08148; H01L 2224/16225; H01L 2224/80895; H01L 2924/1431; H01L 2924/182

(57) ABSTRACT

Apparatuses, systems, assemblies, and techniques related to integrating photonics integrated circuit devices and electronic integrated circuit devices into an assembly or module are described. An integrated module includes a photonics integrated circuit device within an opening of a glass core substrate and an electronic integrated circuit device direct bonded to the photonics integrated circuit device. An optical waveguide is within or on the glass core substrate and has a terminal end edge coupled to the photonics integrated circuit device within the opening.

### BACKGROUND

Higher performance, lower cost, increased miniaturization, and greater packaging density of integrated circuits within integrated circuit devices are ongoing goals of the electronics industry. Furthermore, integrating photonic and electrical circuits can improve system efficiencies by utilizing the superior characteristics of each of these differing technologies. For example, photonic and electrical technologies may be combined to increase data transmission speeds and capacities while reducing costs and energy consumption. An emerging need exists for solutions for the packaging of such photonic and electrical technologies that provide compact, efficient, and high-bandwidth couplings between these mixed technology nodes.

It is with respect to these and other considerations that the present improvements have been needed. Such improvements may become critical as the desire to deploy advanced photonic and electrical circuit systems becomes more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 illustrates a cross-sectional view of an electro-optical IC module having a photonic integrated circuit device direct bonded to an electronic integrated circuit device;

FIGS. 2A and 2B illustrate cross-sectional views of electro-optical IC modules having a photonic integrated circuit device direct bonded to an electronic integrated circuit device and immediately adjacent an optical waveguide;

FIG. 3 illustrates a cross-sectional view of an electro-optical IC module having a photonic integrated circuit device direct bonded to an electronic integrated circuit device using direct bonded interconnects and bonded dielectric material;

FIG. 4 illustrates a cross-sectional view of an electro-optical IC module having a photonic integrated circuit device direct bonded to an electronic integrated circuit device using direct bonded interconnects, and a passive cooling structure adjacent an optical waveguide;

FIG. 5 illustrates a cross-sectional view of an electro-optical IC module having a photonic integrated circuit device direct bonded to an electronic integrated circuit device using direct bonded interconnects, and a passive cooling structure embedded in an encapsulation material;

FIG. 6 illustrates a cross-sectional view of an electro-optical IC module having a photonic integrated circuit device direct bonded to an electronic integrated circuit device using direct bonded interconnects, and an active cooling structure adjacent an optical waveguide;

FIG. 7 illustrates a cross-sectional view of an electro-optical IC module having a photonic integrated circuit device direct bonded to an electronic integrated circuit device using direct bonded interconnects, and an active cooling structure embedded in an encapsulation material;

FIG. 8 is a flow diagram illustrating methods for forming an electro-optical integrated circuit module having a photonic integrated circuit device direct bonded to an electronic integrated circuit device;

FIGS. 9A, 9B, 9C, 9D, 9E, 9F, 9G, 9H, 9I, and 9J illustrate cross-sectional views of an electro-optical IC module evolving as the methods of FIG. 8 are practiced;

FIG. 10 illustrates an example microelectronic device assembly including an electro-optical IC module having integrated photonic and electrical integrated circuit devices;

FIG. 11 illustrates a diagram of an example data server machine employing an electro-optical IC module having integrated photonic and electrical integrated circuit devices; and

FIG. 12 is a functional block diagram of an electronic computing device, all arranged in accordance with at least some implementations of the present disclosure.

### DETAILED DESCRIPTION

One or more embodiments or implementations are now described with reference to the enclosed figures. While specific configurations and arrangements are discussed, this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

Reference is made in the following detailed description to the accompanying drawings, which form a part hereof, wherein like numerals may designate like parts throughout to indicate corresponding or analogous elements. It will be appreciated that for simplicity and/or clarity of illustration, elements illustrated in the figures have not necessarily been drawn to scale. For example, the dimensions of some of the elements may be exaggerated relative to other elements for clarity. Further, it is to be understood that other embodiments may be utilized, and structural and/or logical changes may be made without departing from the scope of claimed subject matter. It should also be noted that directions and references, for example, up, down, top, bottom, over, under, and so on, may be used to facilitate the discussion of the drawings and embodiments and are not intended to restrict the application of claimed subject matter. Therefore, the following detailed description is not to be taken in a limiting sense and the scope of claimed subject matter defined by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe structural relationships between components. It should be understood that these terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features. The term immediately adjacent indicates such features are in direct contact. Furthermore, the terms “substantially,” “close,” “approximately,” “near,” and “about,” generally refer to being within +/−10% of a target value. The term layer as used herein may include a single material or multiple materials. As used in throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. The terms “lateral”, “laterally adjacent” and similar terms indicate two or more components are aligned along a plane orthogonal to a vertical direction of an overall structure. Herein, the term “predominantly” indicates not less than 50% of a particular material or component while the term “substantially pure” indicates not less than 99% of the particular material or component. Unless otherwise indicated, such material percentages are based on atomic percentage. As used herein, the terms “monolithic”, “monolithically integrated”, and similar terms indicate the components of the monolithic overall structure form a indivisible whole not reasonably capable of being separated.

The term “package” generally refers to a self-contained carrier of one or more dice, where the dice are attached to the package substrate, and may be encapsulated for protection, with integrated or wire-boned interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit. Here, the term “dielectric” and the term “insulative and any similar term generally refers to any number of non-electrically conductive materials that make up the structure of a package substrate. For purposes of this disclosure, dielectric material may be incorporated into an integrated circuit package as layers of laminate film or as a resin molded over integrated circuit dice mounted on the substrate. Here, the term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric. Here, the term “assembly” generally refers to a grouping of parts into a single functional unit. The parts may be separate and are mechanically assembled into a functional unit, where the parts may be removable. In another instance, the parts may be permanently bonded together. In some instances, the parts are integrated together. Throughout the specification, and in the claims, the term “connected” means a direct connection, such as electrical, mechanical, or magnetic connection between the things that are connected, without any intermediary devices. The term “coupled” means a direct or indirect connection, such as a direct electrical, mechanical, magnetic or fluidic connection between the things that are connected or an indirect connection, through one or more passive or active intermediary devices.

Apparatuses, systems, architectures, and techniques are described herein related to integration of photonic integrated circuit devices and electronic integrated circuit devices.

As discussed, it is desirable to integrate photonic and electrical circuits for improved system efficiencies such as increased data transmission speeds and capacities, reduced costs, reduced energy consumption, and others. Techniques discussed herein provide for an efficient integrated electronic integrated circuit (EIC) and photonic integrated circuit (PIC) architecture. Herein, the term PIC or PIC device (or, alternatively, integrated optical circuit) indicates a device such as a chip or die that includes photonic components and forms a functioning circuit. The term EIC or EIC device indicates a device such as a chip or die that includes electronic components and forms a functioning circuit. An electronic component detects, generates, transports, and/or processes electrical signals. Furthermore, the integrated EIC/PIC architecture may include a microcontroller, which is a device such as an electronic integrated circuits device that again includes electronic components, typically with one more processor cores, memory, and an input output system. In some embodiments, the microcontroller may be a computer on a single chip. The EIC may be characterized as a first logic device (i.e., logic 1) and the microcontroller may be characterized as a second logic device (i.e., logic 2), or vice versa. Such PICs, EICs, and microcontrollers are separate monolithic devices or dies that are integrated into a system with direct connections therebetween. The discussed techniques provide heterogenous packaging solutions with mixed technology nodes (i.e., PIC and EIC) attached with direct die-to-die connections for high performance photonics packaging. Such packages provide for the assembly of multiple electrical ICs with a PIC engine. Notably, the direct bonds between the chips eliminates the need for solder bumping and improves package scalability. As used herein the term direct bond indicates a bond pad-to-bond pad such as a copper-to-copper connections formed via a hybrid bonding processing.

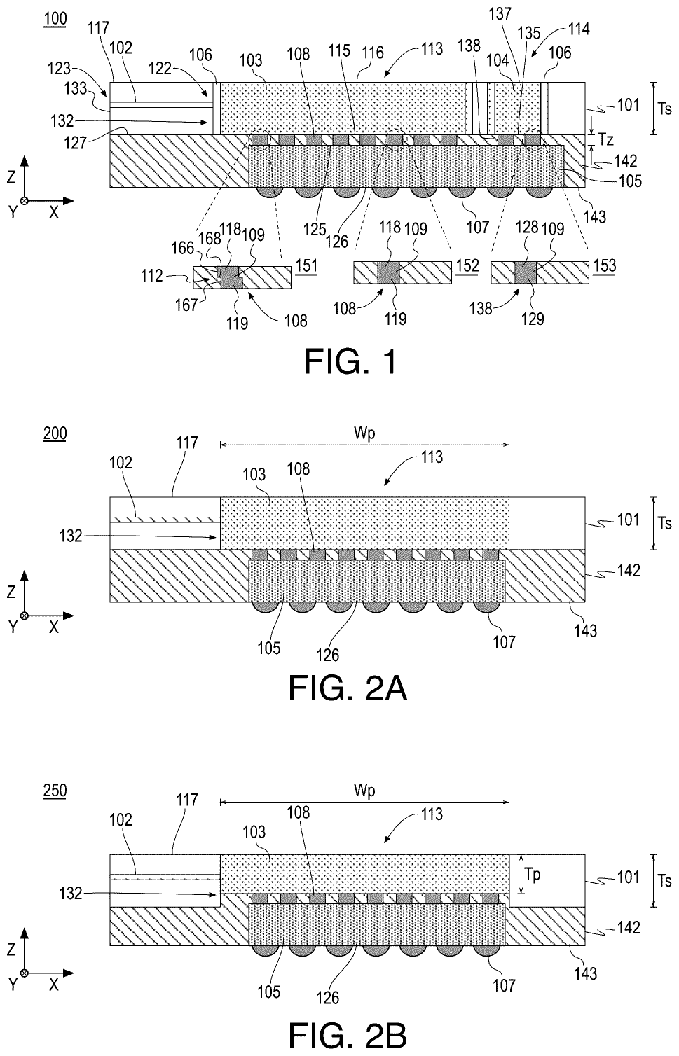

FIG. 1 illustrates a cross-sectional view of an electro-optical IC module 100 having a photonic integrated circuit device 103 direct bonded to an electronic integrated circuit device 105, in accordance with some embodiments. Electro-optical IC module 100 includes at least two IC dies, photonic integrated circuit (PIC) device 103 (e.g., a PIC or PIC die) and electronic integrated circuit (EIC) device 105 (e.g., an EIC, EIC die, or logic 1 die), directly bonded to one another by interconnects 108. Also as shown, PIC device 103 is within an opening 113 of a glass core substrate 101. Herein the terminology within an opening indicates the component is partially or entirely within a volume vacated by and defined by the opening. In some embodiments, electro-optical IC module 100 further includes a microcontroller device 104 (e.g., a microcontroller, microcontroller die, or logic 2 die) directly bonded to EIC device 105 by interconnects 138 such that microcontroller device 104 is also within an opening 114 of glass core substrate 101. By embedding PIC device 103 and microcontroller device 104 within openings 113, 114 of glass core substrate 101 and by providing direct bond interconnects 108, 138 between PIC device 103 and EIC device 105 and between microcontroller device 104 and EIC device 105, the z-height of electro-optical IC module 100 is reduced and shorter connections (and lower latency) are provided. Other advantages of electro-optical IC module 100 will be evident based on the following description.

As discussed, electro-optical IC module 100 includes glass core substrate 101. Glass core substrate 101 may include any suitable glass material such as sodium borosilicate glass. Glass core substrate 101 may also include one or more buildup layers (not shown) on either side thereof. For example, top surface 117 and bottom surface 127 of glass core substrate 101 may be glass or a buildup layer on a central glass core. Glass core substrate 101 includes one or more openings 113, 114 to accommodate PIC device 103 and microcontroller device 104. Furthermore, in the embodiment of FIG. 1, an optical waveguide 102 is within glass core substrate 101 such that a terminal end 122 edge couples to PIC device 103. For example, terminal end 122 of optical waveguide 102 may be exposed at a sidewall 132 within opening 113 of glass core substrate 101. A second terminal end 123 of optical waveguide 102 may be exposed at an outer sidewall 133 of glass core substrate 101 (for edge coupling to another component) or terminal end 123 may couple to another device withing glass core substrate 101. In some embodiments, terminal end 123 may couple to a fiber array unit (FAU) built into glass core substrate 101 or external to glass core substrate 101.

Optical waveguide 102 may be any physical structure that guides electromagnetic waves in the optical spectrum. For example, the material of optical waveguide 102 may be different from or altered from glass core substrate 101 to guide the electromagnetic waves. In some embodiments, optical waveguide 102 is a transparent dielectric material, a separate glass material, an altered glass material (e.g., altered by application of a laser, or chemical treatment such as salt melt), or other. Although illustrated with optical waveguide 102 embedded within a thickness, Ts, of glass core substrate 101, in some embodiments optical waveguide 102 is at or on top surface 117 or at or on bottom surface 127. Although illustrated with respect to a single optical waveguide 102, multiple optical waveguides may couple to PIC device 103 at one or more side surfaces of PIC device 103.

As shown, PIC device 103 is embedded within opening 113 of glass core substrate 101. In some embodiments, opening 113 extends entirely through thickness, Ts, of glass core substrate 101. PIC device 103 and microcontroller device 104 are laterally adjacent glass core substrate 101. In some embodiments, each of PIC device 103, microcontroller device 104, and glass core substrate 101 have a substantially equal thickness, Ts (e.g., PIC device 103 and microcontroller device 104 are of the same thickness, Ts, as glass core substrate 101). In some embodiments, top surface 117 of glass core substrate, top surface 116 of PIC device, and top surface 137 of microcontroller device 104 may be substantially coplanar.

In some embodiments, PIC device 103 and/or microcontroller device 104 are thicker than glass core substrate 101 and extend below bottom surface 127. In some embodiments, PIC device 103 and/or microcontroller device 104 are thinner than glass core substrate 101 and an entirety or portion of interconnects 108 and, optionally, a portion of EIC device 105 are within an opening of glass core substrate 101. In such embodiments, PIC device 103 and microcontroller device 104 may be in a shared opening.

PIC device 103 may be any IC die including one or more photonic components and may additionally include electrical components. Such photonic components and optional electrical components form an electro-optical IC that detects, generates, transports, and/or processes light. Photonics or optical components include lasers, amplifiers, modulators, detectors, multiplexers, demultiplexers, waveguides, power splitters, and others. In the example of FIG. 1, PIC device 103 receives and/or transmits photonic signals through optical waveguide 102. In some embodiments, PIC device 103 includes or is built from a substrate including silicon, silicon nitride, lithium niobite, a compound semiconductor material, such as a III-V material, including indium phosphide (InP) or gallium arsenide (GaAs), or others.

EIC device 105 provides electrical power and/or electrical control signals to PIC device 103 (e.g., via interconnects 108). In a similar manner, EIC device 105 provides electrical power and/or interchanges electrical control signals with microcontroller device 104 (e.g., via interconnects 138), which may also power or signal PIC device 103 via EIC device 105. For example, EIC device 105, PIC device 103, and microcontroller device 104 may exchange electrical power and/or electrical control or data signals in any suitable manner. EIC device 105 and microcontroller device 104 may be fabricated from any suitable semiconductor substrate such as silicon, III-V materials or other compound semiconductor materials, such as gallium arsenide, or others.

As discussed, PIC device 103 and microcontroller device 104 are direct bonded to EIC device 105 by interconnects 108, 138. For example, interconnects 108, 138 may be characterized as direct bond interconnects (DBIs). As shown in enlarged view 152, interconnects 108 include a bond pad 118 of PIC device 103 and a bond pad 119 of EIC device 105. As used herein, the term bond pad indicates a distal surface of a bond interface. Any underlying structure may be below the bond pad such as a thickness of the bond pad, a post, or other interconnect structure. For example, bond pad 118 extends over a surface 115 of PIC device 103 and bond pad 119 extends over a surface 125 of EIC device 105. Bond pads 118, 119 may be any suitable metals such as copper. In some embodiments, interconnects 108 are substantially pure copper. Such direct bonding may be provided using hybrid bonding (or direct bonding) techniques such that bond pads 118, 119 are brought together under pressure and elevated temperature to form interconnects 108. After such bonding, interconnects 108 include a bonding interface 109 between bond pads 118, 119. For example, bonding interface 109 may have a different microstructure than remaining portions of interconnects 108. In some embodiments, bonding interface 109 has a different grain size than remaining portions of interconnects 108. In some embodiments, bonding interface 109 is an interdiffusion region of metals from bond pads 118, 119 having a different grain size than remaining portions of interconnects 108.

In a similar manner, as shown in enlarged view 153, interconnects 138 include a bond pad 128 of microcontroller device 104 and a bond pad 129 of EIC device 105. For example, bond pad 128 extends over a surface 135 of microcontroller device 104 and bond pad 129 extends over surface 125 of EIC device 105. Bond pads 128, 129 may have any characteristics discussed with respect to bond pads 118, 119. Similarly, interconnects 138 are formed in the same manner as interconnects 108 and may have the same properties inclusive of bonding interface 109.

As shown with respect to enlarged view 151, in some embodiments, interconnects 108 may include a misalignment 112 indicative of the hybrid bond of bond pads 118, 119. Misalignment 112 may include, for example, a first sidewall 166 of bond pad 118 misaligned with a second sidewall 167 of bond pad 119 such that a lateral offset 168 (i.e., measured in the x-dimension) is therebetween. In some embodiments, lateral offset 168 is in the range of 10 to 200 nm. For example, lateral offset 168 may be not less than 10 nm, not less than 25 nm, or not less than 50 nm. Although any thicknesses may be used, in some embodiments, PIC device 103, microcontroller device 104, EIC device 105, and glass core substrate 101 may have thicknesses between 15 and 50 microns, thicknesses between 50 and 80 microns, or thicknesses between 75 and 150 microns. A z-height thickness, Tz, between PIC device 103 and EIC device 105 and between microcontroller device 104 and EIC device 105 may be reduced due to deployment of direct or hybrid bonding. In some embodiments, the z-height thickness, Tz, is in the range of 100 to 500 nm, in the range of 250 to 750 nm, or in the range of 500 to 1,000 nm.

In the example of FIG. 1, PIC device 103 and microcontroller device 104 are surrounded by a transparent polymer 106. For example, transparent polymer 106 may be an index matched polymer. As shown, in some embodiments, transparent polymer 106 is between sidewall 132 of glass core substrate 101 and PIC device 103 and between terminal end 122 of optical waveguide 102 and PIC device 103 to optically couple PIC device 103 and optical waveguide 102. Alternatively, transparent polymer 106 may not be deployed and PIC device 103 may abut sidewall 132 of glass core substrate 101 or be immediately adjacent sidewall 132 of glass core substrate 101 such that optical coupling is achieved between optical waveguide 102 and PIC device 103. Such embodiments are discussed herein below.

Furthermore, an encapsulation material 142, such as a mold material, is provided on and laterally adjacent EIC device 105 and on otherwise exposed portions of PIC device 103, microcontroller device 104, and glass core substrate 101. In the example of FIG. 1, encapsulation material 142 is also between interconnects 108, 138. In other examples, a dielectric material is provided between interconnects 108, 138, as discussed herein below. In some embodiments, a bottom surface 143 of encapsulation material 142 is substantially coplanar with a bottom surface 126 of PIC device 105.

As shown, package level interconnects 107 such as solder features may be provided over bottom surface 126 of PIC device 105 to connect to a system level substrate such as a printed circuit board (PCB) or other system substrate. The system level package or device may then be deployed in any suitable form factor device such as a server system, server blade, or the like. Such systems are discussed further herein below.

FIGS. 2A and 2B illustrate cross-sectional views of electro-optical IC modules 200, 250 having photonic integrated circuit device 103 direct bonded to electronic integrated circuit device 105 and immediately adjacent optical waveguide 102, in accordance with some embodiments. In FIGS. 2A and 2B, and elsewhere herein, like numerals are used to identify the same or similar components, and such components may have any characteristics discussed elsewhere herein. Notably, electro-optical IC module 200 is similar to electro-optical IC module 100 except that PIC device 103 is immediately adjacent to or abutted against sidewall 132 of optical waveguide 102. As discussed with respect to FIG. 1, in some embodiments, transparent polymer 106 may be deployed between PIC device 103 and sidewall 132 and between PIC device 103 and optical waveguide 102.

In other embodiments, particularly where pick and place operations allow for high accuracy placement of PIC device 103 or a module including both PIC device 103 and EIC device 105, no transparent polymer may be needed to couple PIC device 103 and optical waveguide 102, nor to secure PIC device 103 within opening 113. As shown, PIC device 103 is embedded within opening 113 of glass core substrate 101 such that opening 113 may extend entirely through thickness, Ts, of glass core substrate 101. PIC device 103 is laterally adjacent glass core substrate 101. In some embodiments, PIC device 103 and glass core substrate 101 have a substantially equal thickness (e.g., PIC device 103 and microcontroller device 104 are of the same thickness, Ts, as glass core substrate 101) such that top surface 117 of glass core substrate and top surface 116 of PIC device may be substantially coplanar.

Electro-optical IC module 200 illustrates an example where microcontroller device 104 is not deployed or where microcontroller device 104 is obscured in the cross-section of FIG. 2. For example, the functionality of microcontroller device 104 may not be needed, may be provided by EIC device 105, or may be provided by a remote controller. However, embodiments without transparent polymer may be deployed in contexts where microcontroller device 104 is used.

Electro-optical IC module 200 illustrates an example where EIC device 105 is within a footprint of PIC device 103, although implementations without transparent polymer are not limited to this context. In this example, the footprint of EIC device 105 is within a lateral width, Wp, of PIC device 103 in the x-dimension, and the same is true in the y-dimension (e.g., a width of EIC device 105 is less than a width of PIC device 103 and a length of EIC device 105 is less than a length of PIC device 103). Using such techniques, both PIC device 103 and EIC device 105 may fit within opening 113, and interconnects 108 may be partially or fully within opening 113 and laterally adjacent glass core substrate 101, as shown with respect to electro-optical IC module 250 of FIG. 2B. Such techniques may further reduce the z-height to electro-optical IC module 250. For example, the thickness, Tp, of PIC device 103 may be less than the thickness, Ts, of glass core substrate 101. In some embodiments, top surface 117 of glass core substrate and top surface 116 of PIC device are substantially coplanar and at least portions of interconnects 108 are within opening 113 and laterally adjacent glass core substrate 101. Such techniques may be deployed with microcontroller device 104 with both PIC device 103 and microcontroller device 104 within a shared opening.

As discussed, in some embodiments, encapsulation material 142 is interspersed between interconnects 108 and/or interconnects 138. In other examples, a dielectric material is provided between interconnects 108, 138, as discussed herein below. In some embodiments, bottom surface 143 of encapsulation material 142 is substantially coplanar with bottom surface 126 of PIC device 105.

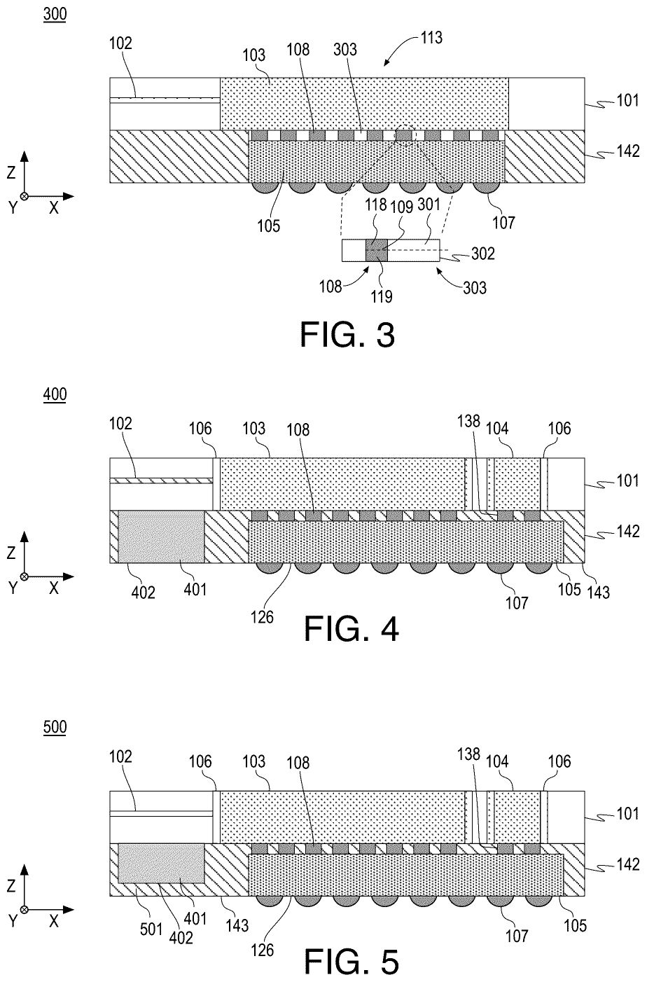

FIG. 3 illustrates a cross-sectional view of electro-optical IC module 300 having photonic integrated circuit device 103 direct bonded to an electronic integrated circuit device 105 using direct bonded interconnects 108 and bonded dielectric material 303, in accordance with some embodiments. As discussed, PIC device 103 and EIC device 105 are direct bonded to form interconnects 108 therebetween. In some embodiments, surfaces of PIC device 103 and EIC device 105 including metallization bond pads 118, 119, respectively, interspersed among dielectric material layers 301, 302, respectively. That is, bond pads 118 are interspersed within dielectric material layer 301 and bond pads 119 are interspersed within dielectric material layer 302. In some embodiments, the patterning of the surfaces matches metal to metal and dielectric to dielectric for hybrid bonding between PIC device 103 and EIC device 105.

Such surface may then be brought together optionally under pressure and/or heat to meld the metal to form interconnects 108 and, optionally, to meld the dielectric material to form dielectric bond 303. Dielectric material layers 301, 302 may include any suitable materials for bonding including silicon oxide, polymers, or others. As discussed, direct bonding of PIC device 103 and EIC device 105 does not necessitate such dielectric material layers 301, 302 bonding. In some embodiments, gaps such as air gaps may be between some or all of interconnects 108 as materials adjacent interconnects 108 do not come into contact during bonding. In some embodiments, deployment of dielectric material layers 301, 302 to form dielectric bond 303 may enhance the strength of the bond between PIC device 103 and EIC device 105 and/or provide electrical isolation between interconnects 108.

FIG. 4 illustrates a cross-sectional view of an electro-optical IC module 400 having photonic integrated circuit device 103 direct bonded to electronic integrated circuit device 105 using direct bonded interconnects 108, and a passive cooling structure 401 adjacent optical waveguide 102, in accordance with some embodiments. In the example of electro-optical IC module 400, passive cooling structure 401 is affixed to glass core substrate 101 laterally adjacent EIC device 105 and vertically adjacent waveguide 102. Herein, the term passive cooling structure indicates a heat removal device that is not powered by another device, operated under the control of another device, or the like.

Passive cooling structure 401 may be any suitable passive cooling structure such as a block or slug of material having a greater thermal conductivity that surrounding encapsulation material 142 and glass core substrate 101. In some embodiments, passive cooling structure 401 is a metal or metal alloy. In some embodiments, passive cooling structure 401 is copper. In some embodiments, passive cooling structure 401 has a thermal conductivity of about 398 W/mK (e.g., the thermal conductivity of copper), glass core substrate 101 has a thermal conductivity of abouts 1.4 W/mK (e.g., the thermal conductivity of borosilicate glass), and encapsulation material 142 has a thermal conductivity in the range of 1 to 5 W/mK. In some embodiments, passive cooling structure 401 has a thermal conductivity of not less than 75 times that of encapsulation material 142 and glass core substrate 101, not less than 200 times that of encapsulation material 142 and glass core substrate 101, or not less than 300 times that of encapsulation material 142 and glass core substrate 101.

In the example of FIG. 4, a bottom surface 402 of passive cooling structure 401 is exposed. Such architectures may provide for a direct contact coupling of passive cooling structure 401 to a heat dissipation device below electro-optical IC module 400. In some embodiments, bottom surface 143 of encapsulation material 142, bottom surface 126 of PIC device 105, and a bottom surface 402 of passive cooling structure 401 are substantially coplanar. In addition or in the alternative, passive cooling structure 401 may couple to a heat dissipation device laterally aligned with electro-optical IC module 400.

FIG. 5 illustrates a cross-sectional view of an electro-optical IC module 500 having photonic integrated circuit device 103 direct bonded to electronic integrated circuit device 105 using direct bonded interconnects 108, and passive cooling structure 401 embedded in encapsulation material 142, in accordance with some embodiments. In the example of electro-optical IC module 500, passive cooling structure 401 is again affixed to glass core substrate 101 laterally adjacent EIC device 105 and vertically adjacent waveguide 102. As shown, in some embodiments, passive cooling structure 401 is embedded under a portion 501 of encapsulation material 142.

In such architectures, bottom surface 402 of passive cooling structure 401 is embedded under a portion 501 of encapsulation material 142 and passive cooling structure 401 may couple to a heat dissipation device laterally aligned with electro-optical IC module 400, as illustrated herein with respect to FIG. 10. In some embodiments, bottom surface 143 of encapsulation material 142 and bottom surface 126 of PIC device 105 are substantially coplanar while bottom surface 402 of passive cooling structure 401 is embedded within encapsulation material 142. The example of FIG. 4 may provide for robust fabrication and protection for passive cooling structure 401.

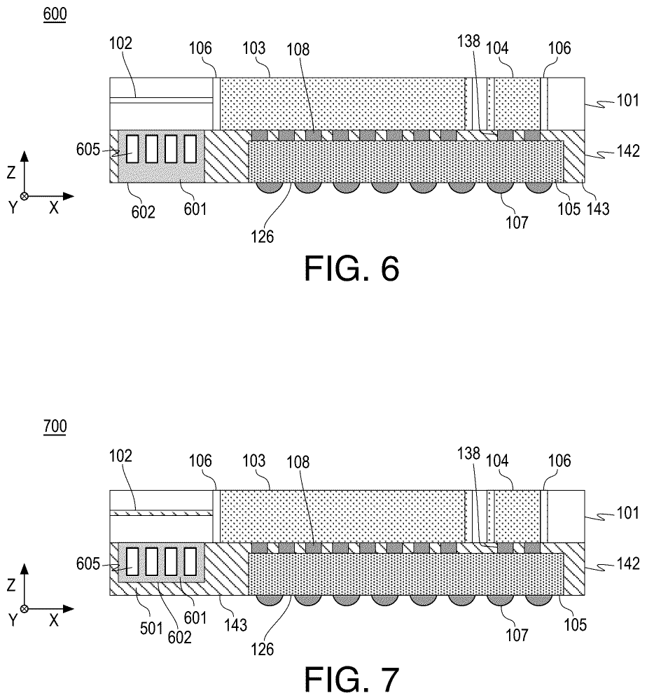

FIG. 6 illustrates a cross-sectional view of an electro-optical IC module 600 having photonic integrated circuit device 103 direct bonded to electronic integrated circuit device 105 using direct bonded interconnects 108, and an active cooling structure 601 adjacent optical waveguide 102, in accordance with some embodiments. In the example of electro-optical IC module 600, active cooling structure 601 is affixed to glass core substrate 101 laterally adjacent EIC device 105 and vertically adjacent waveguide 102. Herein, the term active cooling structure indicates a heat removal device that requires powering or control by an external device or to active cooling structure 601. For example, an active cooling structure may be a fluid flow cooler (as shown), a thermoelectric cooler (TEC), or other device.

Active cooling structure 601 may be any suitable active cooling structure such as a fluid flow cooler (as shown), a thermoelectric cooler (TEC), or other device. In some embodiments, active cooling structure is a fluid flow cooler including microchannels 605. Microchannels 605 are to convey a heat transfer fluid therein to remove heat from electro-optical IC module 600. The heat transfer fluid may be any suitable liquid or gas. As used herein, the term microchannels indicates a channel to convey a heat transfer fluid with the multiple microchannels providing discrete separate channels or a network of channels. Notably, the plural microchannels does not indicate separate channel networks are needed. Such microchannels 605 may be provided in any pattern in the x-y plane such as serpentine patterns, patterns of multiple parallel microchannels 605, or the like. Microchannels 605 couple to a heat exchanger (not shown) that removes heat from and cools the heat transfer fluid before re-introduction to microchannels 605. The flow of fluid within microchannels 605 may be provided by a pump or other fluid flow device. The operation of the heat exchanger, pump, etc. may be controlled by a controller.

In the example of FIG. 6, a bottom surface 602 of active cooling structure 601 is exposed. In some embodiments, bottom surface 143 of encapsulation material 142, bottom surface 126 of PIC device 105, and a bottom surface 602 of active cooling structure 601 are substantially coplanar.

FIG. 7 illustrates a cross-sectional view of an electro-optical IC module 700 having photonic integrated circuit device 103 direct bonded to electronic integrated circuit device 105 using direct bonded interconnects 108, and active cooling structure 601 embedded in encapsulation material 142, in accordance with some embodiments. In the example of electro-optical IC module 700, active cooling structure 601 is affixed to glass core substrate 101 laterally adjacent EIC device 105 and vertically adjacent waveguide 102. As shown, in some embodiments, active cooling structure 601 is embedded under portion 501 of encapsulation material 142. In some embodiments, bottom surface 143 of encapsulation material 142 and bottom surface 126 of PIC device 105 are substantially coplanar while bottom surface 602 of active cooling structure 601 is embedded within encapsulation material 142.

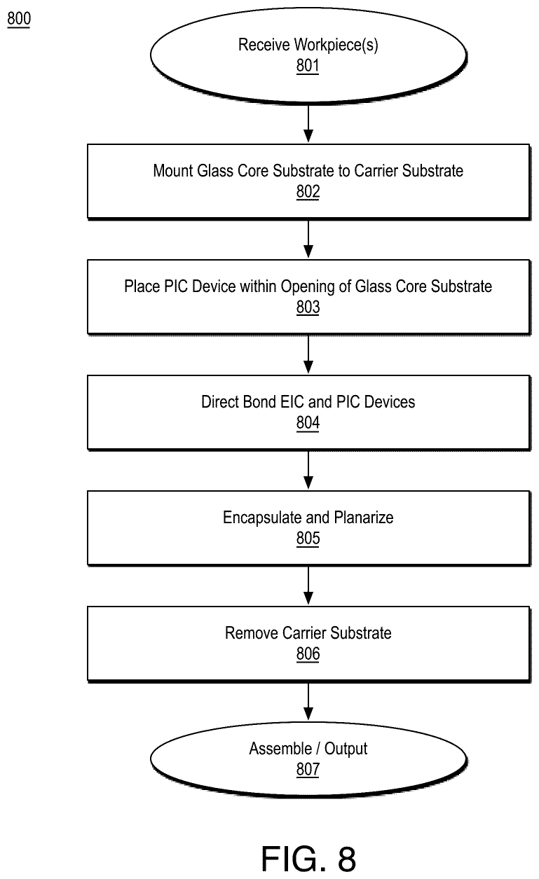

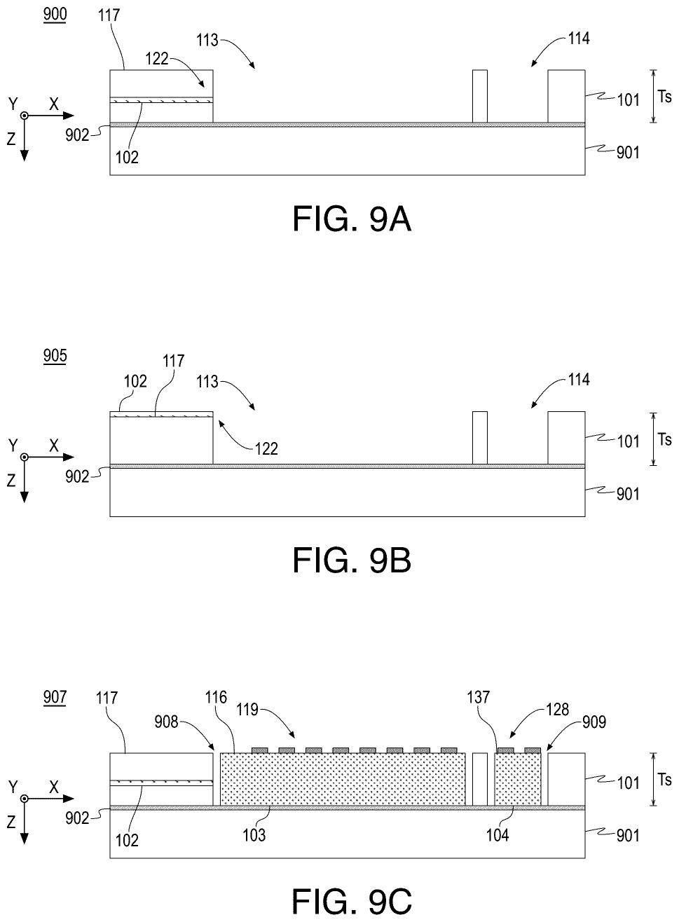

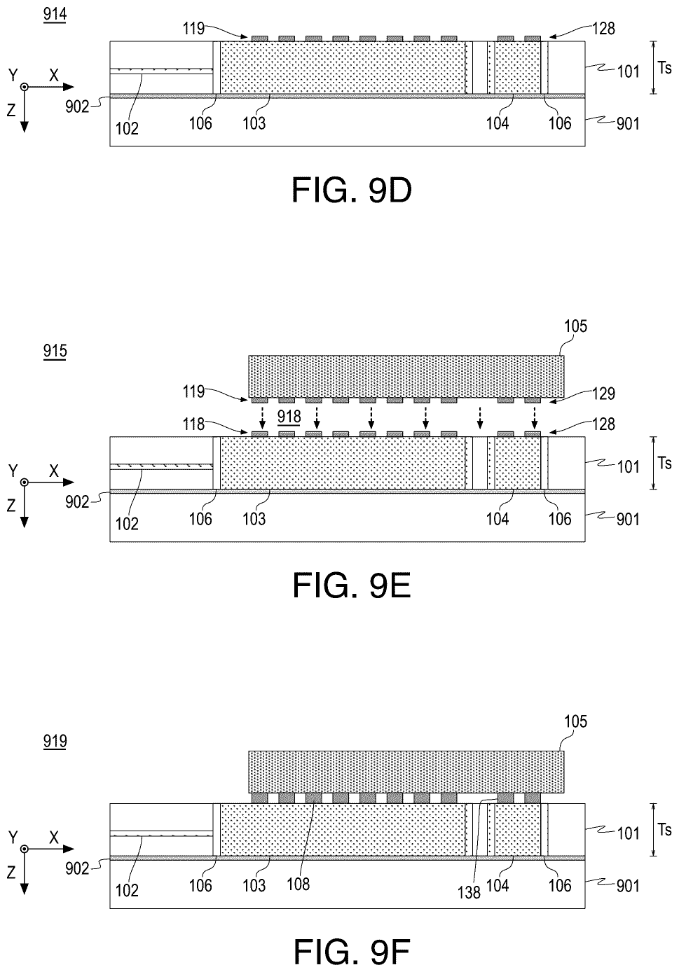

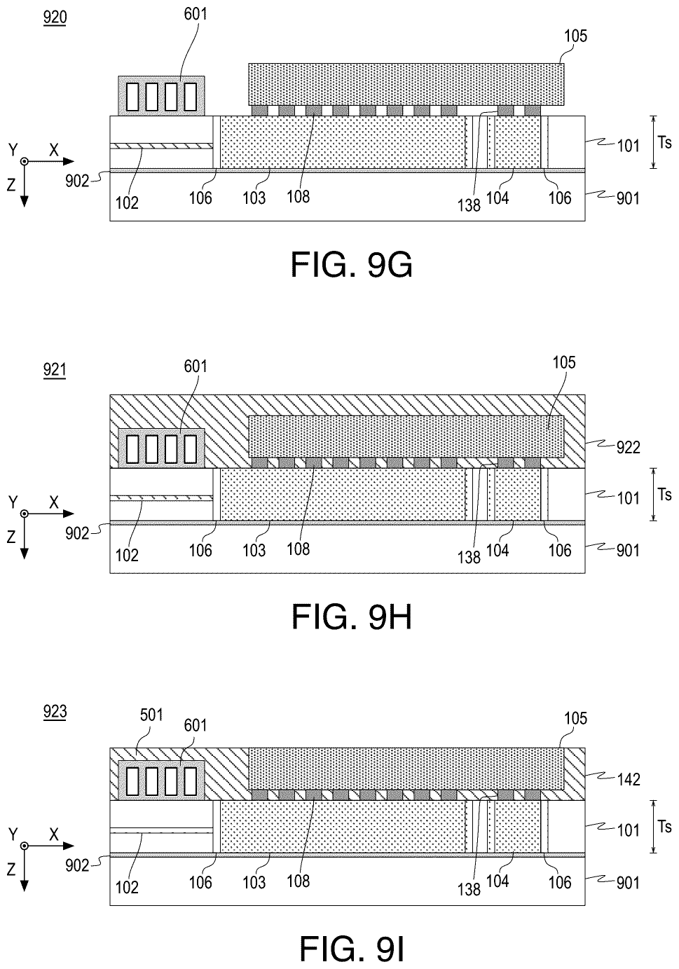

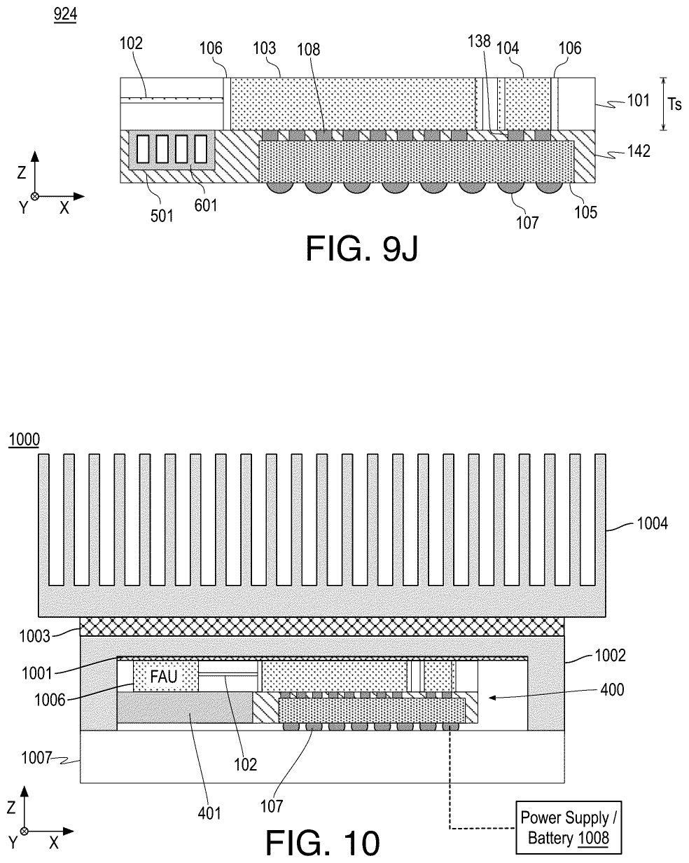

FIG. 8 is a flow diagram illustrating methods 800 for forming an electro-optical integrated circuit module having a photonic integrated circuit device direct bonded to an electronic integrated circuit device, arranged in accordance with some embodiments of the disclosure. Methods 800 may be practiced, for example, to fabricate any of electro-optical IC modules 100, 200, 250, 300, 400, 500, 600, or 700. FIGS. 9A, 9B, 9C, 9D, 9E, 9F, 9G, 9H, 9I, and 9J illustrate cross-sectional views of an electro-optical IC module evolving as methods 800 are practiced, arranged in accordance with some embodiments of the disclosure.

Methods 800 begin at input operation 801, where a workpiece or workpieces are received for processing. In some embodiments, a glass core substrate is received and openings are formed therein using any suitable technique or techniques such as laser drilling, chemical etching, or the like. In some embodiments, a carrier substrate, a PIC device, an EIC device, and a microcontroller device are also received for processing. Such devices may include any devices and/or characteristics discussed herein. Processing continues at operation 802, where the glass core substrate is mounted to the carrier substrate. The glass core substrate includes one or more openings therein and the glass core substrate includes an optical waveguide on or within the glass core substrate that has a terminal end adjacent to at least one of the openings. The glass core substrate may be mounted to the carrier substrate using any suitable technique or techniques. In some embodiments, the glass core substrate is mounted to the carrier substrate by a removable adhesive film. The carrier substrate may be any suitable material such as a glass including borosilicate glass or others. The discussed openings and optical waveguide may be fabricated while the glass core substrate is mounted to the carrier substrate or prior to mounting.

FIG. 9A illustrates a cross-sectional view of an electro-optical integrated circuit structure 900 illustrating glass core substrate 101 mounted to a carrier substrate 901. In the illustrated embodiment, glass core substrate 101 is mounted to carrier substrate 901 using a removable adhesive film 902, although other techniques may be used. As shown, glass core substrate 101 includes openings 113, 114 formed therein and glass core substrate 101 includes optical waveguide 102 having terminal end 122 exposed to opening 113. In the embodiment of FIG. 9A, optical waveguide 102 is formed within a thickness, Ts, of glass core substrate 101.

FIG. 9B illustrates a cross-sectional view of an electro-optical integrated circuit structure 905 illustrating glass core substrate 101 mounted to a carrier substrate 901. In the embodiment of FIG. 9B, glass core substrate 101 includes openings 113, 114 formed therein and glass core substrate 101 includes optical waveguide 102 having terminal end 122 exposed to opening 113.

In the remaining electro-optical integrated circuit structures, the embodiment of FIG. 9A is used for the sake of clarity of presentation; however, analogous structures may be formed from the embodiment of FIG. 9B.

Returning to FIG. 8, processing continues at operation 803, where a PIC device is placed within one of the openings in the glass core substrate. Depending on the critical dimensions and the capabilities of the pick and place operation, the PIC device may be placed immediately adjacent the optical waveguide and no transparent polymer (e.g., index matched polymer) may be needed between the PIC device and the optical waveguide. However, in some contexts, a transparent polymer may be needed.

FIG. 9C illustrates a cross-sectional view of an electro-optical integrated circuit structure 907 similar to electro-optical integrated circuit structure 900 after placing PIC device 103 within opening 113 and microcontroller device 104 within opening 114. PIC device 103 and microcontroller device 104 may be placed within openings 113, 114 using any suitable technique or techniques. In some embodiments, PIC device 103 and microcontroller device 104 are placed using pick and place operations. In the illustrated embodiment, PIC device 103 is not placed within range of optical waveguide 102, and a transparent polymer is needed to bridge gap 908. Similarly, a gap 909 exists between microcontroller device 104 and glass core substrate 101.

FIG. 9D illustrates a cross-sectional view of an electro-optical integrated circuit structure 914 similar to electro-optical integrated circuit structure 907 after formation of transparent polymer 106 within gaps 908, 909 between glass core substrate 101 and PIC device 103 and between glass core substrate 101 and microcontroller device 104, respectively. Transparent polymer 106 may be formed using any suitable technique or techniques such as application directly within gaps 908, 909 and optional removal of excess material.

Returning to FIG. 8, processing continues at operation 804, where an EIC device is hybrid bonded to the PIC device and optional microcontroller device. In some embodiments, surfaces of the PIC device and EIC device include metallization bond pads that are mirror patterns of one another. Optionally, the metal bond pads may be interspersed among dielectric material layers such that the metal bond pads and dielectric material layers have substantially coplanar outer surfaces (refer to FIG. 3). The surfaces of the PIC device and EIC device are then brought together such that at least the metal bond pads (e.g., copper pads) are in contact with one another. Heat and pressure are then applied to form a direct bond between the bond pads.

FIG. 9E illustrates a cross-sectional view of an electro-optical integrated circuit structure 915 similar to electro-optical integrated circuit structure 914 after aligning EIC device 105 such that bond pads 119 of EIC device 105 align with corresponding bond pads 118 of PIC device 103 and bond pads 129 of EIC device 105 align with corresponding bond pads 128 of microcontroller device 104. EIC device 105 is then brought together with PIC device 103 and microcontroller device 104 as shown with respect to arrows 918 to contact pads 119 with bond pads 118 and to contact bond pads 129 with corresponding bond pads 128. Heat and pressure may then be applied to form interconnects 108, 138. FIG. 9F illustrates a cross-sectional view of an electro-optical integrated circuit structure 919 similar to electro-optical integrated circuit structure 915 after forming interconnects 108 from bond pads 119 of EIC device 105 and corresponding bond pads 118 of PIC device 103 and forming interconnects 138 from bond pads 129 of EIC device 105 and corresponding bond pads 128 of microcontroller device 104 using direct or hybrid bonding techniques as discussed herein.

In the embodiments illustrated in FIGS. 9C-9F, PIC device 103 is placed within opening 113 and then EIC device 105 is then directed bonded to the PIC device 103. Alternatively, PIC device 103 and EIC device 105 may be first be direct bonded and then the assembly may be placed in opening 113. In either case, PIC device 103 (e.g., with or without EIC device 105 bonded thereto) is placed within opening 113 as discussed with respect to operation 803.

FIG. 9G illustrates a cross-sectional view of an electro-optical integrated circuit structure 920 similar to electro-optical integrated circuit structure 919 after application of optional active cooling structure 601 on glass core substrate 101 laterally adjacent EIC device 105 and vertically adjacent waveguide 102. Active cooling structure 601 may be applied to glass core substrate 101 using any suitable technique or techniques such as application of an adhesive or double-sided tape. In alternatively embodiments, passive cooling structure 401 may be applied on glass core substrate 101 laterally adjacent EIC device 105 and vertically adjacent waveguide 102.

Returning to FIG. 8, processing continues at operation 805, where the EIC device and optional cooling structure are encapsulated in an encapsulation material such as a mold material or the like. The encapsulation or mold material may be applied using any suitable technique or techniques such as bulk deposition techniques followed by a planarization operation such as chemical mechanical polishing.

FIG. 9H illustrates a cross-sectional view of an electro-optical integrated circuit structure 921 similar to electro-optical integrated circuit structure 920 after application of a bulk encapsulation material 922 on and over EIC device 105, active cooling structure 601, and glass core substrate 101. Bulk encapsulation material 922 may include any suitable encapsulation or mold material such as a plastic, an epoxy, or the like. FIG. 9I illustrates a cross-sectional view of an electro-optical integrated circuit structure 923 similar to electro-optical integrated circuit structure 921 after planarization of bulk encapsulation material 922 to form encapsulation material 142 including portion 501 of encapsulation material 142 over active cooling structure 601.

Returning to FIG. 8, processing continues at operation 806, where the carrier substrate is removed from the assembled electro-optical integrated circuit module. The carrier substrate may be removed using any suitable technique or techniques. In some embodiments, the removable adhesive film is released using UV light treatment or the like. In some embodiments, the discussed techniques assemble multiple electro-optical integrated circuit modules on a panel. In such contexts, each electro-optical integrated circuit module may be singulated after release of the carrier substrate.

FIG. 9J illustrates a cross-sectional view of an electro-optical integrated circuit structure 924 similar to electro-optical integrated circuit structure 923 after removal of carrier substrate 901 and removable adhesive film 902. Notably, electro-optical integrated circuit structure 924 is similar to electro-optical integrated circuit module 700, although any of electro-optical integrated circuit modules 100, 200, 250, 300, 400, 500, 600 or similar modules may be assembled using such techniques.

Processing continues at operation 807, where any remaining assembly features may be competed, and the electro-optical integrated circuit module may be affixed to a system substrate and the resultant package may be output for incorporation into any suitable electronic device such as a server machine, or the like.

FIG. 10 illustrates an example microelectronic device assembly 1000 including an electro-optical IC module having integrated photonic and electrical integrated circuit devices, in accordance with some embodiments. Although illustrated with electro-optical IC module 400, any electro-optical IC module discussed herein may be deployed in microelectronic device assembly 1000. As shown in FIG. 10, microelectronic device assembly 1000 may include an electro-optical IC module such as electro-optical IC module 400 mounted to system substrate 1007 via interconnects 107 such as solder bumps. System substrate 1007 may be any suitable substrate such as a mother board, printed circuit board, or the like. In some embodiments, optical waveguide 102 of electro-optical IC module 400 couples to a fiber unit array (FAU) 1006.

Microelectronic device assembly 1000 further includes a power supply 1008 coupled to one or more of system substrate 1007, electro-optical IC module 400, or other components of microelectronic device assembly 1000. Power supply 1008 may include a battery, voltage converter, power supply circuitry, or the like. Microelectronic device assembly 1000 further includes a thermal interface material (TIM) 1001 disposed on top surfaces of electro-optical IC module 400. TIM 1001 may include any suitable thermal interface material and may be characterized as TIM 1. Integrated heat spreader 1002 having a surface on TIM 1001 extends over electro-optical IC module 400 and is mounted to system substrate 1007. As shown, passive cooling structure 400 of electro-optical IC module 400 may be in direct contact with integrated heat spreader 1002 or another heat dissipation device.

Microelectronic device assembly 1000 further includes TIM 1003 disposed on a top surface of integrated heat spreader 1002. TIM 1003 may include any suitable thermal interface material and may be characterized as TIM 2. TIM 1001 and TIM 1003 may be the same materials, or they may be different. Heat sink 1004 (e.g., an exemplary heat dissipation device or thermal solution) is on TIM 1003 and dissipates heat generated by electro-optical IC module 400. Microelectronic device assembly 1000 may be used in nay suitable form factor such as a server form factor system or a desktop form factor system. In other contexts, a heat solution such as a heat pipe or heat spreader may be mounted directly on TIM 1001. Such assemblies may be used in smaller form factor devices. Other heat dissipation devices may be used.

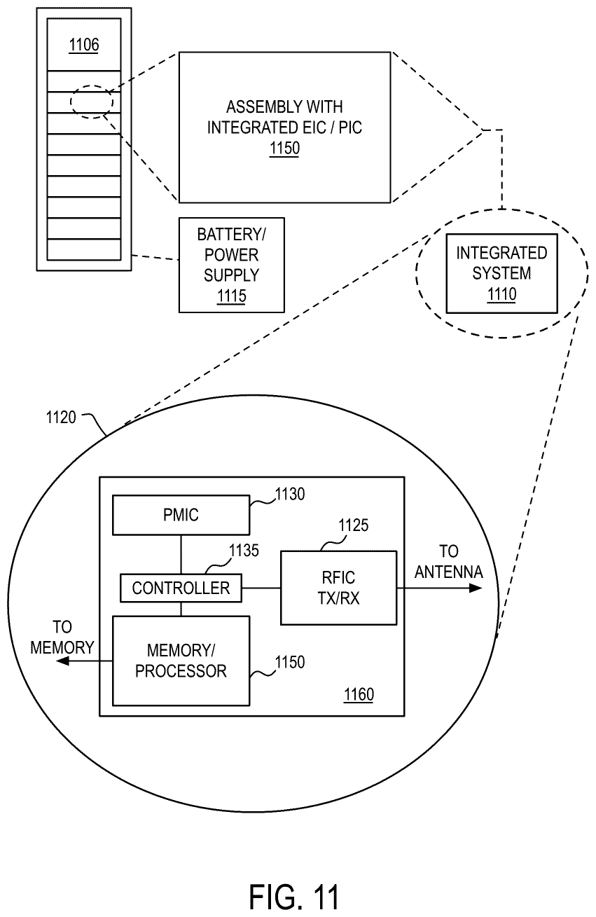

FIG. 11 illustrates a diagram of an example data server machine 1106 employing an electro-optical IC module having integrated photonic and electrical integrated circuit devices, in accordance with some embodiments. Server machine 1106 may be any commercial server, for example, including any number of high-performance computing platforms disposed within a rack and networked together for electronic data processing, which in the exemplary embodiment includes one or more devices 1150 employing an electro-optical IC module having integrated photonic and electrical integrated circuit devices.

Server machine 1106 includes a battery and/or power supply 1115 to provide power to devices 1150, and to provide, in some embodiments, power delivery functions such as power regulation. Devices 1150 may be deployed as part of a package-level integrated system 1110. Integrated system 1110 is further illustrated in the expanded view 1120. In the exemplary embodiment, devices 1150 (labeled “Memory/Processor”) includes at least one memory chip (e.g., RAM), and/or at least one processor chip (e.g., a microprocessor, a multi-core microprocessor, or graphics processor, or the like) having the characteristics discussed herein. In an embodiment, device 1150 is a microprocessor including an SRAM cache memory. As shown, device 1150 may include an electro-optical IC module having integrated photonic and electrical integrated circuit devices, as discussed herein. For example, any electro-optical IC module discussed herein may be deployed in device 1150. Device 1150 may be further coupled to (e.g., communicatively coupled to) a board, an interposer, or system substrate 1160 along with, one or more of a power management IC (PMIC) 1130, RF (wireless) IC (RFIC) 1125, including a wideband RF (wireless) transmitter and/or receiver (TX/RX) (e.g., including a digital baseband and an analog front end module further includes a power amplifier on a transmit path and a low noise amplifier on a receive path), and a controller 1135 thereof. In some embodiments, RFIC 1125, PMIC 1130, controller 1135, and device 1150 include IC modules having photonic and electrical ICs and an integrated switchable waveguide device.

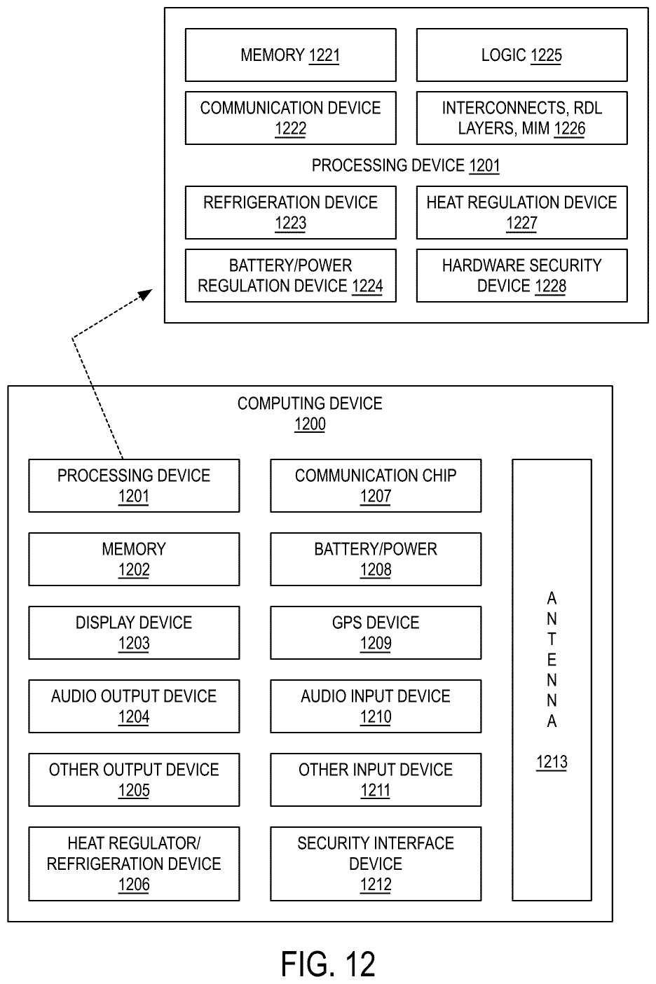

FIG. 12 is a block diagram of an example computing device 1200, in accordance with some embodiments. For example, one or more components of computing device 1200 may include any of the electro-optical IC modules having integrated photonic and electrical integrated circuit devices discussed herein. A number of components are illustrated in FIG. 12 as being included in computing device 1200, but any one or more of these components may be omitted or duplicated, as suitable for the application. In some embodiments, some or all of the components included in computing device 1200 may be attached to one or more printed circuit boards (e.g., a motherboard). In some embodiments, various ones of these components may be fabricated onto a single system-on-a-chip (SoC) die. Additionally, in various embodiments, computing device 1200 may not include one or more of the components illustrated in FIG. 12, but computing device 1200 may include interface circuitry for coupling to the one or more components. For example, computing device 1200 may not include a display device 1203, but may include display device interface circuitry (e.g., a connector and driver circuitry) to which display device 1203 may be coupled. In another set of examples, computing device 1200 may not include an audio output device 1204, other output device 1205, global positioning system (GPS) device 1209, audio input device 1210, or other input device 1211, but may include audio output device interface circuitry, other output device interface circuitry, GPS device interface circuitry, audio input device interface circuitry, audio input device interface circuitry, to which audio output device 1204, other output device 1205, GPS device 1209, audio input device 1210, or other input device 1211 may be coupled.

Computing device 1200 may include a processing device 1201 (e.g., one or more processing devices). As used herein, the term “processing device” or “processor” indicates a device that processes electronic data from registers and/or memory to transform that electronic data into other electronic data that may be stored in registers and/or memory (e.g., SRAM). Processing device 1201 may include a memory 1221, a communication device 1222, a refrigeration device 1223, a battery/power regulation device 1224, logic 1225, interconnects 1226 (i.e., optionally including redistribution layers (RDL) or metal-insulator-metal (MIM) devices), a heat regulation device 1227, and a hardware security device 1228.

Processing device 1201 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 1200 may include a memory 1202, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 1202 includes memory that shares a die with processing device 1201. This memory may be used as cache memory and may include embedded dynamic random-access memory (eDRAM) or spin transfer torque magnetic random-access memory (STT-M RAM).

Computing device 1200 may include a heat regulation/refrigeration device 1206. Heat regulation/refrigeration device 1206 may maintain processing device 1201 (and/or other components of computing device 1200) at a predetermined low temperature during operation.

In some embodiments, computing device 1200 may include a communication chip 1207 (e.g., one or more communication chips). For example, the communication chip 1207 may be configured for managing wireless communications for the transfer of data to and from computing device 1200. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 1207 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 1207 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1207 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1207 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 1207 may operate in accordance with other wireless protocols in other embodiments. Computing device 1200 may include an antenna 1213 to facilitate wireless communications and/or to receive other wireless communications (such as AM or FM radio transmissions).

In some embodiments, communication chip 1207 may manage wired communications, such as electrical, optical, or any other suitable communication protocols (e.g., the Ethernet). As noted above, communication chip 1207 may include multiple communication chips. For instance, a first communication chip 1207 may be dedicated to shorter-range wireless communications such as Wi-Fi or Bluetooth, and a second communication chip 1207 may be dedicated to longer-range wireless communications such as GPS, EDGE, GPRS, CDMA, WiMAX, LTE, EV-DO, or others. In some embodiments, a first communication chip 1207 may be dedicated to wireless communications, and a second communication chip 1207 may be dedicated to wired communications.

Computing device 1200 may include battery/power circuitry 1208. Battery/power circuitry 1208 may include one or more energy storage devices (e.g., batteries or capacitors) and/or circuitry for coupling components of computing device 1200 to an energy source separate from computing device 1200 (e.g., AC line power).

Computing device 1200 may include a display device 1203 (or corresponding interface circuitry, as discussed above). Display device 1203 may include any visual indicators, such as a heads-up display, a computer monitor, a projector, a touchscreen display, a liquid crystal display (LCD), a light-emitting diode display, or a flat panel display, for example.

Computing device 1200 may include an audio output device 1204 (or corresponding interface circuitry, as discussed above). Audio output device 1204 may include any device that generates an audible indicator, such as speakers, headsets, or earbuds, for example.

Computing device 1200 may include an audio input device 1210 (or corresponding interface circuitry, as discussed above). Audio input device 1210 may include any device that generates a signal representative of a sound, such as microphones, microphone arrays, or digital instruments (e.g., instruments having a musical instrument digital interface (MIDI) output).

Computing device 1200 may include a GPS device 1209 (or corresponding interface circuitry, as discussed above). GPS device 1209 may be in communication with a satellite-based system and may receive a location of computing device 1200, as known in the art.

Computing device 1200 may include other output device 1205 (or corresponding interface circuitry, as discussed above). Examples of the other output device 1205 may include an audio codec, a video codec, a printer, a wired or wireless transmitter for providing information to other devices, or an additional storage device.

Computing device 1200 may include other input device 1211 (or corresponding interface circuitry, as discussed above). Examples of the other input device 1211 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1200 may include a security interface device 1212. Security interface device 1212 may include any device that provides security measures for computing device 1200 such as intrusion detection, biometric validation, security encode or decode, access list management, malware detection, or spyware detection.

Computing device 1200, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The following examples pertain to further embodiments, and specifics in the examples may be used anywhere in one or more embodiments.

In one or more first embodiments, an apparatus or electro-optical module comprises a photonic integrated circuit (PIC) device within an opening in a glass core substrate, the PIC device comprising a plurality of first metal bond pads over a surface of the PIC device, an electronic integrated circuit (EIC) device comprising a plurality of second metal bond pads over a surface of the EIC device, wherein the first metal bond pads are directly bonded to corresponding ones of the second metal bond pads, and an optical waveguide on or within the glass core substrate, the optical waveguide comprising a terminal end edge coupled to the PIC device within the opening.

In one or more second embodiments, further to the first embodiments, a second surface of the PIC device opposite the surface is substantially coplanar with an upper surface of the glass core substrate.

In one or more third embodiments, further to the first or second embodiments, the apparatus or electro-optical module further comprises a microcontroller device within a second opening in the glass core substrate, the microcontroller device comprising a plurality of third metal bond pads over a surface of the microcontroller device, such that the third metal bond pads are directly bonded to corresponding ones of the second metal bond pads of the EIC device.

In one or more fourth embodiments, further to the first through third embodiments, the apparatus or electro-optical module further comprises a bonding interface between each of the first metal bond pads of the PIC device and the corresponding ones of the second metal bond pads of the EIC device.

In one or more fifth embodiments, further to the first through fourth embodiments, the bonding interface comprises an interdiffusion region of metals from the first and second bond pads.

In one or more sixth embodiments, further to the first through fifth embodiments, the PIC device is abutted against a sidewall of the opening in the glass core substrate or a transparent polymer is between and in contact with the PIC device and the sidewall of the opening.

In one or more seventh embodiments, further to the first through sixth embodiments, the opening extends through an entirety of a thickness of the glass core substrate.

In one or more eighth embodiments, further to the first through seventh embodiments, the apparatus or electro-optical module further comprises a passive cooling structure laterally adjacent the EIC device and on the glass core substrate vertically adjacent the optical waveguide.

In one or more ninth embodiments, further to the first through eighth embodiments, the apparatus or electro-optical module further comprises an active cooling device laterally adjacent the EIC device and on the glass core substrate vertically adjacent the optical waveguide.

In one or more tenth embodiments, further to the first through ninth embodiments, the active cooling device comprises one or more microchannels to flow cooling fluid therein.

In one or more eleventh embodiments, further to the first through tenth embodiments, the apparatus or electro-optical module further comprises an encapsulation material laterally adjacent the EIC device and on the glass core substrate, the encapsulation material comprising a surface opposite the glass core substrate that is substantially coplanar with a second surface of the EIC device opposite the surface of the EIC device.

In one or more twelfth embodiments, a system comprises a system substrate or board and an apparatus or electro-optical module in accordance with any of the first through eleventh embodiments coupled to the system substrate or board.

In one or more thirteenth embodiments, a system comprises a system substrate, and an electro-optical module coupled to the system substrate, the electro-optical module comprising a photonic integrated circuit (PIC) device within an opening in a glass core substrate, the PIC device directly connected to the EIC device by interconnects therebetween, and an optical waveguide on or within the glass core substrate, the optical waveguide comprising a terminal end edge coupled to the PIC device within the opening.

In one or more fourteenth embodiments, further to the thirteenth embodiments, a surface of the PIC device opposite the EIC device is substantially coplanar with a surface of the glass core substrate.

In one or more fifteenth embodiments, further to the thirteenth or fourteenth embodiments, the system further comprises a microcontroller device within a second opening in the glass core substrate, the microcontroller directly connected to the EIC device by interconnects therebetween.

In one or more sixteenth embodiments, further to the thirteenth through fifteenth embodiments, the opening extends through an entirety of a thickness of the glass core substrate.

In one or more seventeenth embodiments, a method comprises mounting a glass core substrate to a carrier substrate, the glass core substrate comprising an opening therein and the glass core substrate comprising optical waveguide on or within the glass core substrate and having a terminal end adjacent the opening, direct bonding an electronic integrated circuit (EIC) device to a photonic integrated circuit (PIC) device, the direct bonding coupling a plurality of first metal bond pads over a surface of the PIC device directly to corresponding ones of a plurality of second metal bond pads over a surface of the EIC device, placing the PIC device within the opening, forming an encapsulation material over the EIC device and the glass core substrate, and removing the glass core substrate from the carrier substrate.

In one or more eighteenth embodiments, further to the seventeenth embodiments, said direct bonding of the PIC device to the EIC device is performed after said placing the PIC device within the opening.

In one or more nineteenth embodiments, further to the seventeenth or eighteenth embodiments, the method further comprises planarizing the encapsulation material to provide a surface of the encapsulation material opposite the glass core substrate that is substantially coplanar with the surface of the EIC device.

In one or more twentieth embodiments, further to the seventeenth through nineteenth embodiments, the method further comprises direct bonding a microcontroller device within a second opening in a glass core substrate to the EIC device, the direct bonding coupling a plurality of third metal bond pads over a surface of the microcontroller device directly to corresponding ones of the second metal bond pads of the EIC device.

In one or more twenty-first embodiments, further to the seventeenth through ieth embodiments, the method further comprises providing a transparent polymer between and in contact with the PIC device and a sidewall of the opening.

In one or more twenty-second embodiments, further to the seventeenth through twenty-first embodiments, the method further comprises securing a passive cooling structure or an active cooling device laterally adjacent the EIC device and on the glass core substrate vertically adjacent the optical waveguide.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

What is claimed is:

1. An apparatus, comprising:
a photonic integrated circuit (PIC) device within an opening in a glass core substrate, the PIC device comprising a plurality of first metal bond pads over a surface of the PIC device;
an electronic integrated circuit (EIC) device comprising a plurality of second metal bond pads over a surface of the EIC device, wherein the first metal bond pads are directly bonded to corresponding ones of the second metal bond pads; and
an optical waveguide on or within the glass core substrate, the optical waveguide comprising a terminal end edge coupled to the PIC device within the opening.

2. The apparatus of claim 1, wherein a second surface of the PIC device opposite the surface is substantially coplanar with an upper surface of the glass core substrate.

3. The apparatus of claim 1, further comprising:
a microcontroller device within a second opening in the glass core substrate, the microcontroller device comprising a plurality of third metal bond pads over a surface of the microcontroller device, wherein the third metal bond pads are directly bonded to corresponding ones of the second metal bond pads of the EIC device.

4. The apparatus of claim 1, further comprising a bonding interface between each of the first metal bond pads of the PIC device and the corresponding ones of the second metal bond pads of the EIC device.

5. The apparatus of claim 4, wherein the bonding interface comprises an interdiffusion region of metals from the first and second bond pads.

6. The apparatus of claim 1, wherein the PIC device is abutted against a sidewall of the opening in the glass core substrate or a transparent polymer is between and in contact with the PIC device and the sidewall of the opening.

7. The apparatus of claim 1, wherein the opening extends through an entirety of a thickness of the glass core substrate.

8. The apparatus of claim 1, further comprising:
a passive cooling structure laterally adjacent the EIC device and on the glass core substrate vertically adjacent the optical waveguide.

9. The apparatus of claim 1, further comprising:
an active cooling device laterally adjacent the EIC device and on the glass core substrate vertically adjacent the optical waveguide, wherein the active cooling device comprises one or more microchannels to flow cooling fluid therein.

10. The apparatus of claim 1, further comprising:
an encapsulation material laterally adjacent the EIC device and on the glass core substrate, the encapsulation material comprising a surface opposite the glass core substrate that is substantially coplanar with a second surface of the EIC device opposite the surface of the EIC device.

11. A system, comprising:
a system substrate; and
an electro-optical module coupled to the system substrate, the electro-optical module comprising:
a photonic integrated circuit (PIC) device within an opening in a glass core substrate, the PIC device directly connected to the EIC device by interconnects therebetween; and
an optical waveguide on or within the glass core substrate, the optical waveguide comprising a terminal end edge coupled to the PIC device within the opening.

12. The system of claim 11, wherein a surface of the PIC device opposite the EIC device is substantially coplanar with a surface of the glass core substrate.

13. The system of claim 11, further comprising:
a microcontroller device within a second opening in the glass core substrate, the microcontroller directly connected to the EIC device by interconnects therebetween.

14. The system of claim 11, wherein the opening extends through an entirety of a thickness of the glass core substrate.

15. A method, comprising:
mounting a glass core substrate to a carrier substrate, the glass core substrate comprising an opening therein and the glass core substrate comprising optical waveguide on or within the glass core substrate and having a terminal end adjacent the opening;
direct bonding an electronic integrated circuit (EIC) device to a photonic integrated circuit (PIC) device, the direct bonding coupling a plurality of first metal bond pads over a surface of the PIC device directly to corresponding ones of a plurality of second metal bond pads over a surface of the EIC device; and
placing the PIC device within the opening;
forming an encapsulation material over the EIC device and the glass core substrate; and
removing the glass core substrate from the carrier substrate.

16. The method of claim 15, wherein said direct bonding of the PIC device to the EIC device is performed after said placing the PIC device within the opening.

17. The method of claim 15, further comprising:
planarizing the encapsulation material to provide a surface of the encapsulation material opposite the glass core substrate that is substantially coplanar with the surface of the EIC device.

18. The method of claim 15, further comprising:
direct bonding a microcontroller device within a second opening in a glass core substrate to the EIC device, the direct bonding coupling a plurality of third metal bond pads over a surface of the microcontroller device directly to corresponding ones of the second metal bond pads of the EIC device.

19. The method of claim 15, further comprising:
providing a transparent polymer between and in contact with the PIC device and a sidewall of the opening.

20. The method of claim 15, further comprising:
securing a passive cooling structure or an active cooling device laterally adjacent the EIC device and on the glass core substrate vertically adjacent the optical waveguide.
